(19) United States
(12) Patent Application Publication
(10) Pub. No.: US 2025/0359069 A1
(43) Pub. Date: Nov. 20, 2025

(54) SEMICONDUCTOR DEVICE

(71) Applicant: Samsung Electronics Co., Ltd., Suwon-si (KR)

(72) Inventors: Myoungsu Son, Suwon-si (KR); Daeeun Jeong, Suwon-si (KR)

(21) Appl. No.: 18/929,979

(22) Filed: Oct. 29, 2024

(30) Foreign Application Priority Data
May 16, 2024 (KR) 10-2024-0064142

(51) Int. Cl. H10B 61/00; H10N 50/01; H10N 50/10

(52) U.S. Cl. CPC H10B 61/22; H10N 50/01; H10N 50/10

(57) ABSTRACT

A semiconductor device includes a semiconductor substrate that includes a cell region, a core/peri, and a key region, a lower interlayer insulating layer, a first interlayer insulating layer, a first etch stop layer, and a lower conductive region that is on the cell region and the core/peri region and is in the lower interlayer insulating layer, a recess that is in the first interlayer insulating layer and is on the key region, and a first oxide layer that is on a bottom portion of the recess and is on sidewalls of the recess. A width of an upper portion of the recess in a first direction that is parallel to a lower surface of the first interlayer insulating layer is greater than a width of the bottom portion of the recess in the first direction.

### CROSS-REFERENCE TO RELATED APPLICATION

This application is based on and claims priority under 35 U.S.C. § 119 to Korean Patent Application No. 10-2024-0064142, filed on May 16, 2024, in the Korean Intellectual Property Office, the disclosure of which is incorporated by reference herein in its entirety.

### TECHNICAL FIELD

The present disclosure relates to a semiconductor device. More particularly, the present disclosure relates to a semiconductor device including a metal wiring layer.

### BACKGROUND

Along with the development of electronic technology, down-scaling of integrated circuit devices has rapidly progressed, and the line widths and pitches of metal wiring layers included in integrated circuit devices have been miniaturized. Accordingly, there is a need to improve the electrical reliability of metal wiring layers by suppressing a resistance increase and leakage current of the metal wiring layers and suppressing the electromigration of metals.

### SUMMARY

The present disclosure provides a semiconductor device having excellent operation characteristics and an improved integration density.

In addition, the problems to be solved by the technical idea of the present disclosure are not limited to the problem mentioned above, and other problems could be clearly understood by those of ordinary skill in the art from the description below.

The present disclosure provides semiconductor devices described below to solve the technical problems.

According to an aspect of the present disclosure, there is provided a semiconductor device including a semiconductor substrate that includes a cell region, a core/peri region at least partially surrounding the cell region, and a key region between the cell region and the core/peri region, a lower interlayer insulating layer on the cell region, the key region, and the core/peri region, a first interlayer insulating layer on the lower interlayer insulating layer, a first etch stop layer between the lower interlayer insulating layer and the first interlayer insulating layer, and a lower conductive region that is on the cell region and the core/peri region and is in the lower interlayer insulating layer, a recess that is in the first interlayer insulating layer and is on the key region, and a first oxide layer that is on a bottom portion of the recess and is on sidewalls of the recess, where a width of an upper portion of the recess in a first direction that is parallel to a lower surface of the first interlayer insulating layer is greater than a width of the bottom portion of the recess in the first direction.

According to another aspect of the present disclosure, there is provided a semiconductor device including a semiconductor substrate that includes a cell region, a key region adjacent to the cell region, and a core/peri region at least partially surrounding the cell region and the key region, a lower interlayer insulating layer on the cell region, the key region, and the core/peri region, a lower conductive region that is on the cell region and the core/peri region and is in the lower interlayer insulating layer, a first etch stop layer on the lower interlayer insulating layer, a liner on the first etch stop layer, a first interlayer insulating layer on the liner, an upper conductive region that is in the first interlayer insulating layer and at least partially overlaps the lower conductive region in a first direction that is perpendicular to a lower surface of the lower interlayer insulating layer, at least one recess, wherein a width of an upper portion of each of the at least one recess in a second direction that is perpendicular to the first direction is greater than a width of a bottom portion of each of the at least one recess in the second direction, and a first oxide layer that has a uniform thickness in the first direction and is on the bottom portion of each of the at least one recess and sidewalls of each of the at least one recess.

According to another aspect of the present disclosure, there is provided a semiconductor device including a substrate that includes a cell region, a key region and a core/peri region, a lower interlayer insulating layer on the cell region, the key region, and the core/peri region, a lower conductive region that is on the cell region and the core/peri region and is in the lower interlayer insulating layer, a first etch stop layer on the lower interlayer insulating layer, a liner on the first etch stop layer, a first interlayer insulating layer on the liner, an upper conductive region that at least partially overlaps the lower conductive region in a first direction that is perpendicular to a lower surface of the lower interlayer insulating layer, a barrier metal layer that at least partially surrounds a bottom portion of the upper conductive region and sidewalls of the upper conductive region, an outer oxide layer that at least partially surrounds an outer wall of the barrier metal layer and is in the first interlayer insulating layer, at least one recess that is in the first interlayer insulating layer and is on the key region, wherein each of the at least one recess includes sidewalls that are sloped in the first direction, and a first oxide layer that has a uniform thickness in the first direction, contacts the first etch stop layer, is on the sidewalls of each of the at least one recess, wherein the outer oxide layer includes a substantially same material as the first oxide layer, and wherein a thickness of the outer oxide layer in a second direction that is perpendicular to the first direction is substantially the same as a thickness of the first oxide layer in the second direction.

### BRIEF DESCRIPTION OF THE DRAWINGS

Embodiments of the present disclosure will be more clearly understood from the following detailed description taken in conjunction with the accompanying drawings in which:

FIG. 1 is a circuit diagram illustrating a cell array of a variable resistance memory device according to some embodiments;

FIG. 2 is a circuit diagram illustrating a magnetoresistive memory cell of FIG. 1;

FIG. 3 is a perspective view of the magnetoresistive memory cell of FIG. 2;

FIGS. 4A and 4B illustrate a write operation of a magnetic tunnel junction (MTJ) layer constituting the magnetoresistive memory cell of FIG. 1;

FIG. 5 is a top view illustrating a variable resistance memory device according to some embodiments;

FIGS. 6 to 21 are cross-sectional views illustrating, in a process order, a fabrication process of a variable resistance memory device according to some embodiments;

FIG. 22 is a block diagram illustrating a variable resistance memory device according to some embodiments;

FIG. 23 is a block diagram illustrating a data processing system including a variable resistance memory device according to some embodiments; and

FIG. 24 is a block diagram illustrating a data processing system including a variable resistance memory device according to some embodiments.

### DETAILED DESCRIPTION

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and case of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct (i.e., no intervening elements therebetween) or indirect physical and/or electrical connection. Components or layers described with reference to “overlap” in a particular direction may be at least partially obstructed by one another when viewed along a line extending in the particular direction or in a plane perpendicular to the particular direction.

Hereinafter, embodiments are described in detail with reference to the accompanying drawings. Like reference numerals in the drawings denote like elements, and thus their repetitive description will be omitted.

The embodiments may allow various kinds of change or modification and various changes in form, and specific embodiments will be illustrated in drawings and described in detail in the specification. However, it should be understood that the specific embodiments do not limit a scope but include every modified, equivalent, or replaced one within the disclosed technical scope. In the description of the embodiments, when it is determined that a particular description of relevant well-known features may obscure the essentials, a detailed description thereof is omitted.

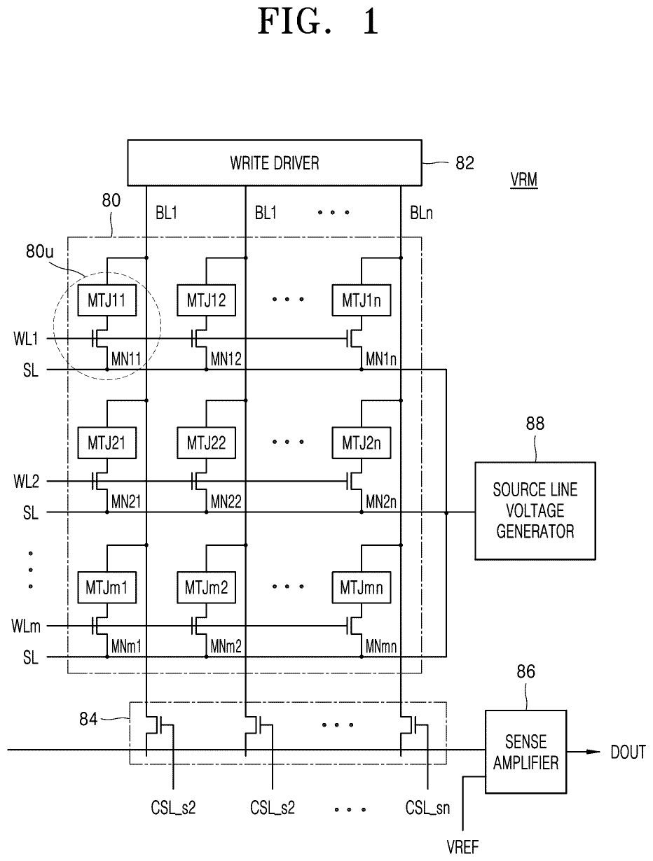

FIG. 1 is a circuit diagram illustrating a cell array of a variable resistance memory device VRM according to some embodiments.

Particularly, a magnetoresistive memory device may be one example of the variable resistance memory device VRM. The magnetoresistive memory device may be a magnetic random access memory (MRAM). The variable resistance memory device VRM may include a variable resistance layer, i.e., a magnetic tunnel junction (MTJ) layer.

The variable resistance memory device VRM may include a magnetoresistive memory cell array 80. The magnetoresistive memory cell array 80 may be referred to as a memory cell array (or a cell array). The magnetoresistive memory cell array 80 may be connected to a write driver 82, a select circuit 84, a source line voltage generator 88, and a sense amplifier 86.

The magnetoresistive memory cell array 80 may include a plurality of magnetoresistive memory cells 80u. A magnetoresistive memory cell 80u may be simply referred to as a memory cell. The magnetoresistive memory cell array 80 may include a plurality of word lines WL1 to WLm and a plurality of bit lines BL1 to BLn. The magnetoresistive memory cell array 80 may have a magnetoresistive memory cell 80u between each of the plurality of word lines WL1 to WLm and each of the plurality of bit lines BL1 to BLn.

The magnetoresistive memory cell array 80 may include cell transistors MN11 to MNmn having gates connected to the plurality of word lines WL1 to WLm, and magnetic tunnel junction (MTJ) layers MTJ11 to MTJmn each connected between each of the cell transistors MN11 to MNmn and each of the plurality of bit lines BL1 to BLn and constituting a variable resistance layer.

The respective sources of the cell transistors MN11 to MN1n may be connected to a source line SL. The select circuit 84 may selectively connect the plurality of bit lines BL1 to BLn to the sense amplifier 86 in response to column select signals CSL_sl to CSL_sn. The sense amplifier 86 may generate output data DOUT by amplifying the difference between an output voltage signal of the select circuit 84 and a reference voltage VREF.

The write driver 82 is connected to the plurality of bit lines BL1 to BLn, generates a program current based on write data, and provides the program current to the plurality of bit lines BL1 to BLn. To magnetize the MTJ layers MTJ11 to MTJmn in the magnetoresistive memory cell array 80, a voltage higher or greater than a voltage applied to the plurality of bit lines BL1 to BLn may be applied to the source line SL. The source line voltage generator 88 may generate a source line drive voltage and provide the source line drive voltage to the source line SL of the magnetoresistive memory cell array 80.

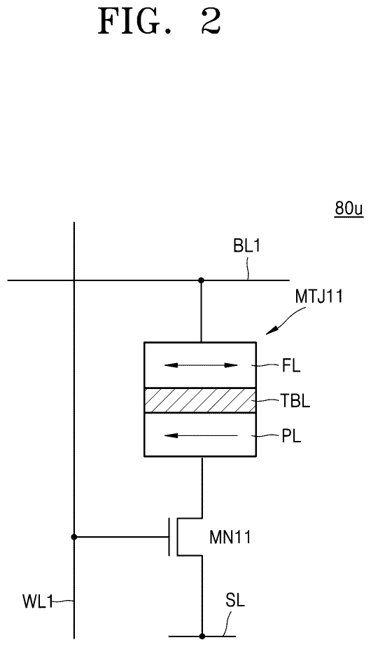

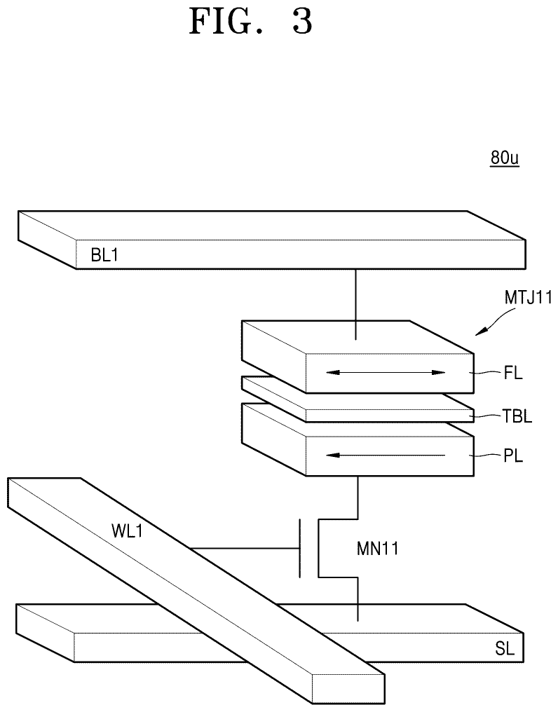

FIG. 2 is a circuit diagram illustrating a magnetoresistive memory cell 80u of FIG. 1, and FIG. 3 is a perspective view of the magnetoresistive memory cell 80u of FIG. 2.

Particularly, as shown in FIG. 2, the magnetoresistive memory cell 80u may include a cell transistor MN11 including an N-type metal oxide semiconductor (NMOS) transistor and an MTJ layer MTJ11. The cell transistor MN11 has a gate connected to a word line WL1 and a source connected to a source line SL. The MTJ layer MTJ11 is connected between the drain of the cell transistor MN11 and a bit line BL1.

As shown in FIG. 3, the MTJ layer MTJ11 may include a pinned layer PL having a pinned constant magnetization direction, a free layer FL magnetized in the direction of a magnetic field applied from the outside, and a tunnel barrier layer TBL formed of an insulating layer between the pinned layer PL and the free layer FL.

In some embodiments, the pinned layer PL may include iron manganese (FeMn), iridium manganese (IrMn), platinum manganese (PtMn), manganese oxide (MnO), manganese sulfide (MnS), manganese telluride (MnTe), manganese difluoride (MnF₂), iron difluoride (FcF₂), iron dichloride (FeCl₂), iron oxide (FeO), cobalt dichloride (CoCl₂), cobalt oxide (CoO), nickel dichloride (NiCl₂), nickel oxide (NiO), chromium (Cr), iron (Fe), nickel (Ni), cobalt (Co), ruthenium (Ru), iridium (Ir), rhodium (Rh), or the like.

In some embodiments, the tunnel barrier layer TBL may include aluminum oxide or magnesium oxide. In some embodiments, the free layer FL may be a ferromagnetic substance including at least one of Fe, Ni, and Co.

The MTJ layer MTJ11 of FIG. 3 may be included in a cell constituting spin transfer torque (STT)-MRAM. For a write operation of the STT-MRAM, a logic-high voltage may be applied to the word line WL1 to turn the cell transistor MN11 on and a write current may be applied between the bit line BL1 and the source line SL.

For a read operation of the STT-MRAM, a logic-high voltage may be applied to the word line WL1 to turn the cell transistor MN11 on and a read current may be applied in the direction from the bit line BL1 to the source line SL to identify data, stored in the magnetoresistive memory cell 80u, according to the resistance value of the MTJ layer MTJ11 in response to the read current.

The resistance value of the MTJ layer MTJ11 may depend on the magnetization direction of the free layer FL. For example, in the MTJ layer MTJ11, the magnetization direction of the free layer FL may be parallel to the magnetization direction of the pinned layer PL. In this case, the MTJ layer MTJ11 may have a low resistance value and data ‘0’ may be read. Alternatively, in the MTJ layer MTJ11, the magnetization direction of the free layer FL may be antiparallel to the magnetization direction of the pinned layer PL. In this case, the MTJ layer MTJ11 may have a high resistance value and data ‘1’ may be read.

Although FIGS. 2 and 3 show a horizontal magnetic device in which the magnetization directions of the free layer FL and the pinned layer PL of the MTJ layer MTJ11 are horizontal, in another embodiment, a vertical magnetic device in which the magnetization directions of the free layer FL and the pinned layer PL are vertical may be used.

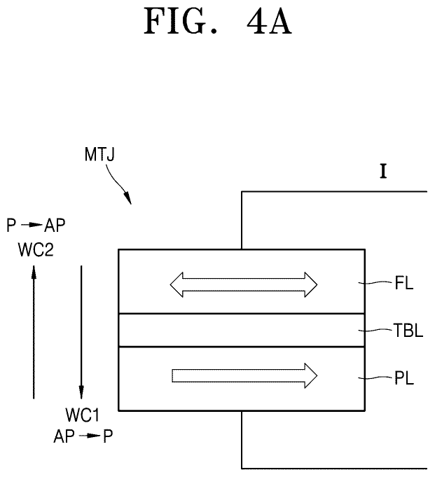

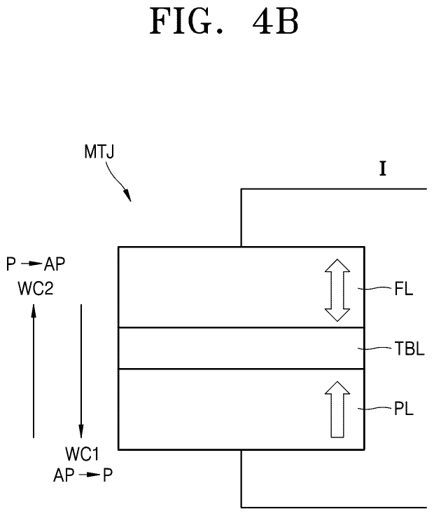

FIGS. 4A and 4B illustrate a write operation of an MTJ layer constituting a magnetoresistive memory cell of FIG. 1.

Particularly, FIG. 4A shows a horizontal magnetic device in which the magnetization directions of the free layer FL and the pinned layer PL of an MTJ layer MTJ are horizontal. The MTJ layer MTJ of which the magnetization direction is horizontal may be a case where a current moving direction is substantially perpendicular to a magnetization easy axis. FIG. 4B shows a vertical magnetic device in which the magnetization directions of the free layer FL and the pinned layer PL are vertical. An MTJ layer MTJ of which the magnetization direction is vertical may be a case where a current moving direction is substantially parallel to a magnetization easy axis.

The magnetization direction of the free layer FL may be determined according to the directions of first and second write currents WC1 and WC2 flowing through the MTJ layer MTJ. For example, when the first write current WC1 is applied, free electrons having the same spin direction as the pinned layer PL apply a torque to the free layer FL. Accordingly, the free layer FL may be magnetized so as to be parallel (P) to the pinned layer PL.

When the second write current WC2 is applied, electrons having a spin direction opposite to that of the pinned layer PL return to the free layer FL and apply a torque to the free layer FL. Accordingly, the free layer FL may be magnetized so as to be anti-parallel (AP) to the pinned layer PL. That is, the magnetization direction of the free layer FL in the MTJ layer MTJ may be changed by an STT.

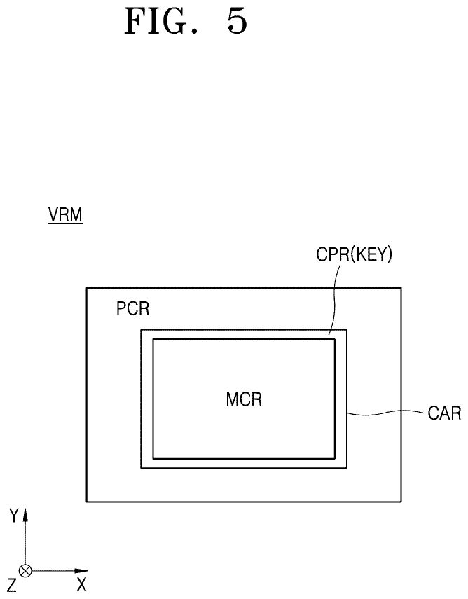

FIG. 5 is a top view illustrating a variable resistance memory device VRM according to some embodiments.

In some embodiments, the variable resistance memory device VRM may be a magnetoresistive memory device. The variable resistance memory device VRM may include a cell array region CAR and a peripheral circuit region PCR surrounding at least a portion of the cell array region CAR.

The cell array region CAR may include a region in which the magnetoresistive memory cell array 80 of FIG. 1, i.e., a memory cell array, is arranged. The cell array region CAR may be a region in which the plurality of magnetoresistive memory cells 80u of FIGS. 1 and 2, i.e., memory cells, are arranged.

The cell array region CAR may include a main cell region MCR in which the plurality of magnetoresistive memory cells 80u of FIGS. 1 and 2, i.e., memory cells (or active cells), are arranged and a cell periphery region CPR, which is outside the main cell region MCR, and in which a key region KEY is arranged.

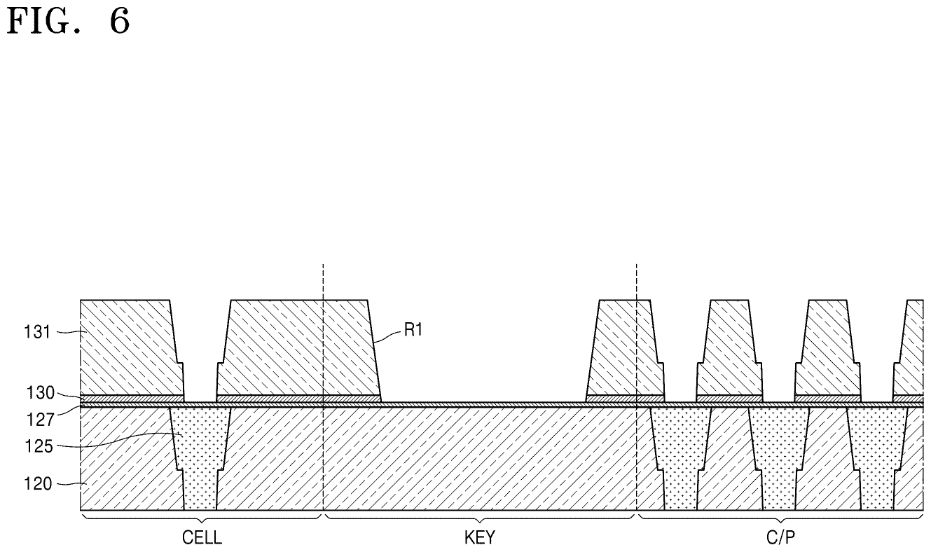

The peripheral circuit region PCR may include a region in which peripheral circuits and peripheral transistors configured to control the cell array region CAR are arranged. The peripheral circuit region PCR may be a region in which core/peri circuits are arranged. That is, the peripheral circuit region PCR may include a core/peri region C/P (see FIG. 6).

The cell array region CAR may include the cell periphery region CPR between the main cell region MCR and the peripheral circuit region PCR. The cell periphery region CPR may be a region surrounding at least a portion of the main cell region MCR. The peripheral circuit region PCR may be a region surrounding at least a portion of the cell periphery region CPR. The cell periphery region CPR may include the key region KEY used for a manufacturing process.

FIGS. 6 to 21 are cross-sectional views illustrating, in a process order, a fabrication process of a variable resistance memory device according to some embodiments.

Referring to FIG. 6, a substrate 110 may include a cell region CELL, a key region KEY, and a core/peri region C/P. The cell region CELL of FIGS. 6 to 21 may correspond to the main cell region MCR of FIG. 5. The key region KEY may be between the cell region CELL and the core/peri region C/P. A lower interlayer insulating layer 120, a lower conductive region 125, a first etch stop layer 127, a liner 130, and a first interlayer insulating layer 131 may be on the substrate 110.

The lower interlayer insulating layer 120 may include an insulating layer made of an oxide layer, a silicon nitride (SiN) layer, or a combination thereof. The lower conductive region 125 may be formed by penetrating or extending into the lower interlayer insulating layer 120. The lower conductive region 125 may include various conductive regions, e.g., a wiring layer, a contact plug, a transistor, and the like. The lower conductive region 125 may include polysilicon, a metal, a conductive metal nitride, metal silicide, or a combination thereof.

The first etch stop layer 127, the liner 130, and the first interlayer insulating layer 131 may be on the lower interlayer insulating layer 120. The first etch stop layer 127 may include nitride, such as SiN, silicon oxynitride (SiON), silicon carbonitride (SiCN), or silicon oxycarbonitride (SiOCN). The liner 130 may be formed on the first etch stop layer 127 and include aluminum nitride (AlN). The liner 130 may have a uniform thickness in a vertical direction that is perpendicular to the lower surface of the lower interlayer insulating layer 120, may be on the key region KEY, and is free from overlap with the bottom portion of the recess in the vertical direction. The first interlayer insulating layer 131 may include an insulating layer made of an oxide layer, a SiN layer, or a combination thereof.

A portion of the first interlayer insulating layer 131 may be etched to form one or more recesses in each of the cell region CELL, the key region KEY, and the core/peri region C/P. In this case, a recess formed in the key region KEY may be referred to as a first recess R1. In a process of etching the first interlayer insulating layer 131, the liner 130 beneath the first interlayer insulating layer 131 to be etched may also be etched. That is, in a process of forming the first recess R1, the upper surface of the first etch stop layer 127 may be exposed. In some embodiments, a width of an upper portion of the recess R1 in a horizontal direction that is parallel to a lower surface of the lower interlayer insulating layer 120 is greater than a width of the bottom portion of the recess R1 in the horizontal direction (e.g., the sidewalls of the recess R1 are sloped in the vertical direction).

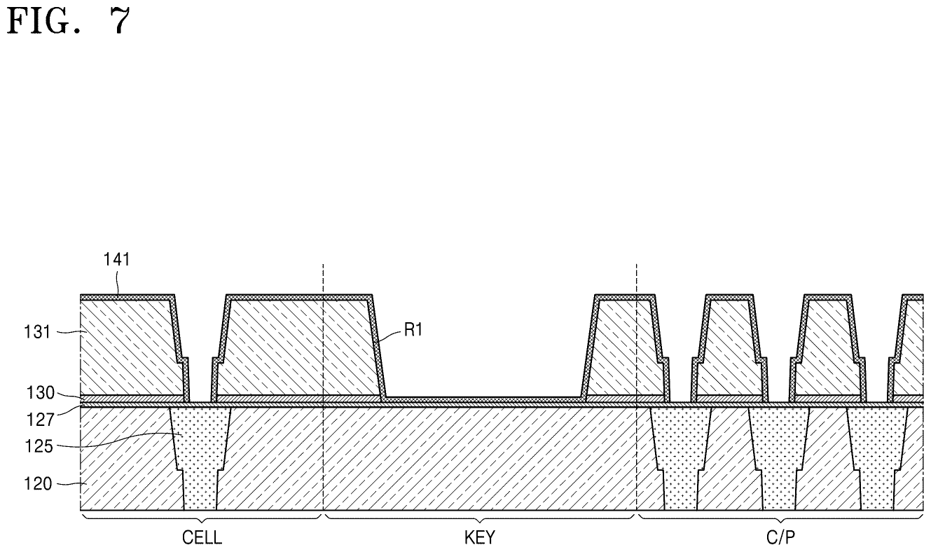

Referring to FIG. 7, a first oxide layer 141 may be formed on the sidewalls of the recesses formed in the cell region CELL, the key region KEY, and the core/peri region C/P and the exposed upper surface of the first interlayer insulating layer 131. In embodiments, the first oxide layer 141 may be formed with a conformal thickness (e.g., a uniform thickness). In embodiments, the first oxide layer 141 may also be formed on a bottom portion and the sidewalls of the first recess R1 in the key region KEY.

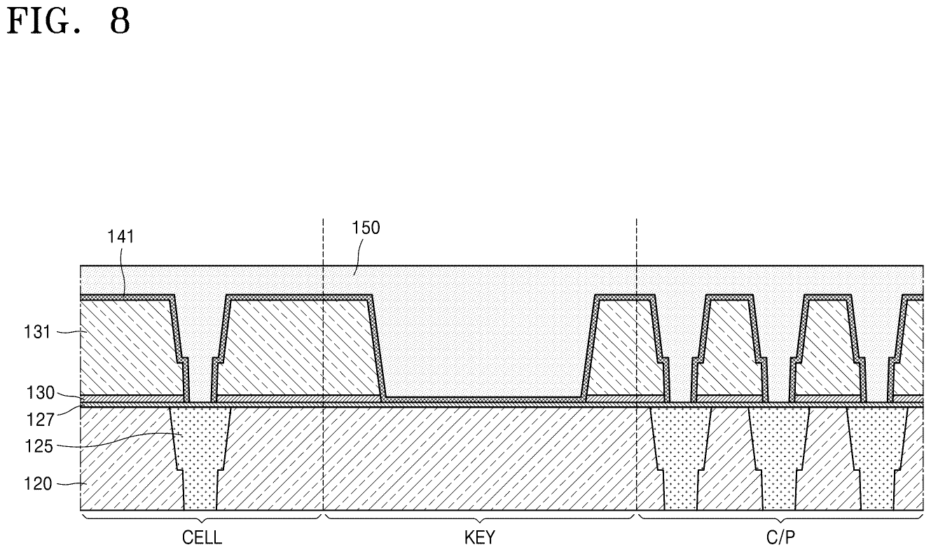

Referring to FIG. 8, an insulating structure 150 covering or overlapping the first oxide layer 141 and covering or in all the recesses formed in the cell region CELL, the key region KEY, and the core/peri region C/P may be formed.

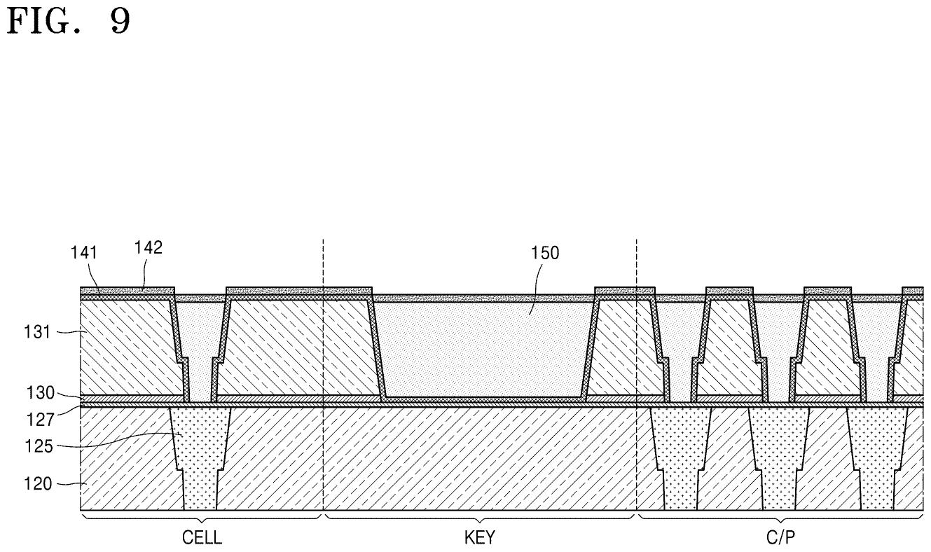

Next, referring to FIG. 9, a portion of the insulating structure 150 may be etched until the upper surface of the first oxide layer 141 deposited on the first interlayer insulating layer 131 is exposed, and a second oxide layer 142 may be conformally deposited on a result of the etching. In this case, the etching of the insulating structure 150 may be performed by an etchback process.

In embodiments, the thickness of the second oxide layer 142 may be greater than the thickness of the first oxide layer 141 in a direction that is perpendicular a lower surface of the lower interlayer insulating layer 120. In embodiments, the second oxide layer 142 may include a material different from that of the first oxide layer 141, but the present disclosure is not limited thereto, and the first oxide layer 141 may include the same material as the second oxide layer 142. The second oxide layer 142 may be deposited with the same thickness in each of the cell region CELL, the key region KEY, and the core/peri region C/P in a direction that is perpendicular the lower surface of the lower interlayer insulating layer 120. Because the second oxide layer 142 is conformally deposited on both the exposed upper surface of the first oxide layer 141 formed on the first interlayer insulating layer 131 and the exposed upper surface of the insulating structure 150 filling the recesses, after performing the process of FIG. 9, the upper surface of the second oxide layer 142 may have different vertical levels or heights relative to the lower surface of the lower interlayer insulating layer 120 in a vertical direction that is perpendicular the lower surface of the lower interlayer insulating layer 120 according to regions. That is, the vertical level (or height) of the second oxide layer 142 deposited in a region in which a recess is formed may be lower than the vertical level (or height) of the second oxide layer 142 deposited in a region in which no recess is formed relative to the lower surface of the lower interlayer insulating layer 120 in the vertical direction.

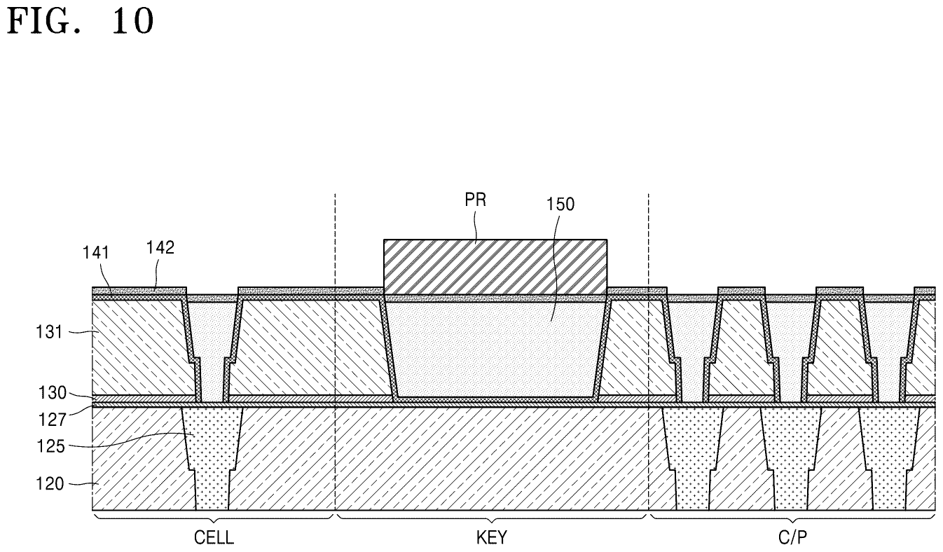

Referring to FIG. 10, a photoresist PR may be applied on a portion of the key region KEY. The photoresist PR may be selectively applied only on a region in which the first recess R1 (see FIG. 6) filled with or including the insulating structure 150 is arranged.

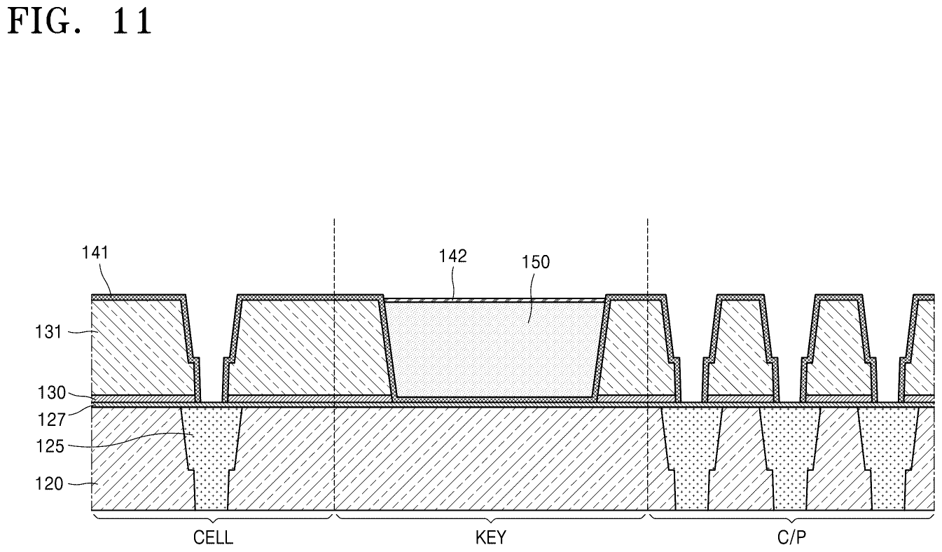

Referring to FIG. 11, first, the second oxide layer 142 may be removed. In embodiments, the second oxide layer 142 may be removed by an etchback process. After performing the etchback process, at a portion covered or overlapped by the photoresist PR in the key region KEY, the second oxide layer 142 deposited beneath the photoresist PR may remain without being removed. After removing the second oxide layer 142, the insulating structure 150 filling or in the recesses in the cell region CELL and the core/peri region C/P may also be removed. In a process of removing the insulating structure 150 in the cell region CELL and the core/peri region C/P, the first etch stop layer 127 beneath the insulating structure 150 may remain without being removed. That is, the upper surface of the first etch stop layer 127 may be exposed. Finally, the photoresist PR covering or overlapping the portion of the key region KEY may be removed to obtain a result of FIG. 11. That is, the second oxide layer 142 may conformally remain only on the upper surface of the insulating structure 150 filling or in the first recess R1 (see FIG. 6) in the portion of the key region KEY.

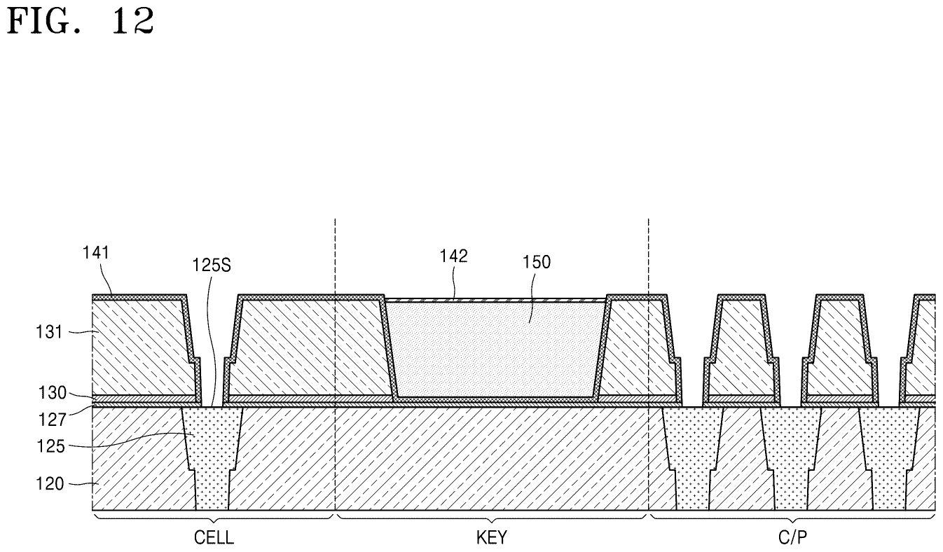

Referring to FIG. 12, the first etch stop layer 127 exposed through bottom portions of the recesses formed in the cell region CELL and the core/peri region C/P may be removed. By removing the first etch stop layer 127, portions of the upper surface of the lower conductive region 125 may be exposed. In embodiments, the first etch stop layer 127 may include AlN.

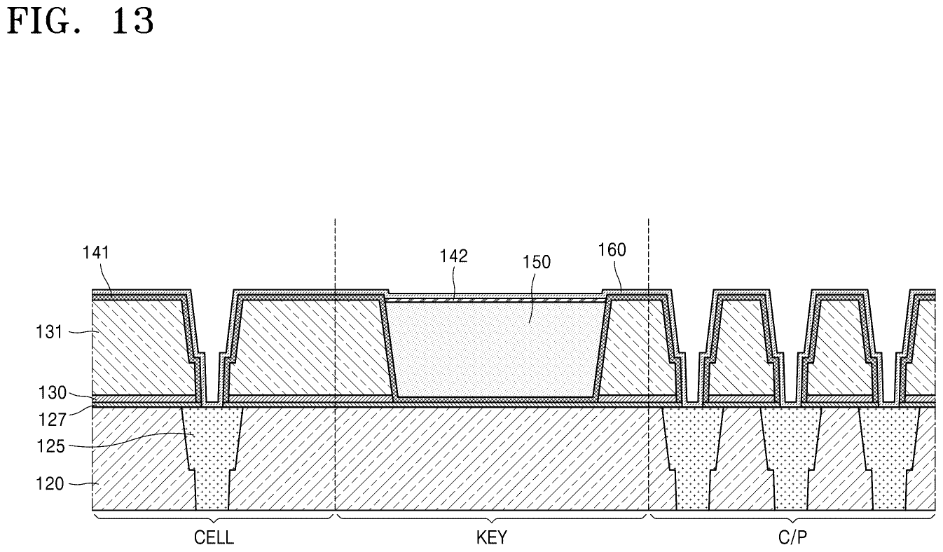

Referring to FIG. 13, a barrier metal layer 160 may be deposited on first and second oxide layers 141 and 142. The barrier metal layer 160 may include metal nitride, such as tungsten nitride, tantalum nitride, or titanium nitride, and/or a metal, such as tantalum or titanium. In embodiments, the barrier metal layer 160 may be deposited with a conformal thickness. The barrier metal layer 160 may cover or overlap all of the upper surfaces of the first and second oxide layers 141 and 142, the sidewalls of the exposed recesses, and the exposed portions of the upper surface of the lower conductive region 125 in each of or on the cell region CELL, the key region KEY, and the core/peri region C/P. The portions of the upper surface of the lower conductive region 125, which are exposed in the previous process, may be covered or overlapped again by depositing the barrier metal layer 160.

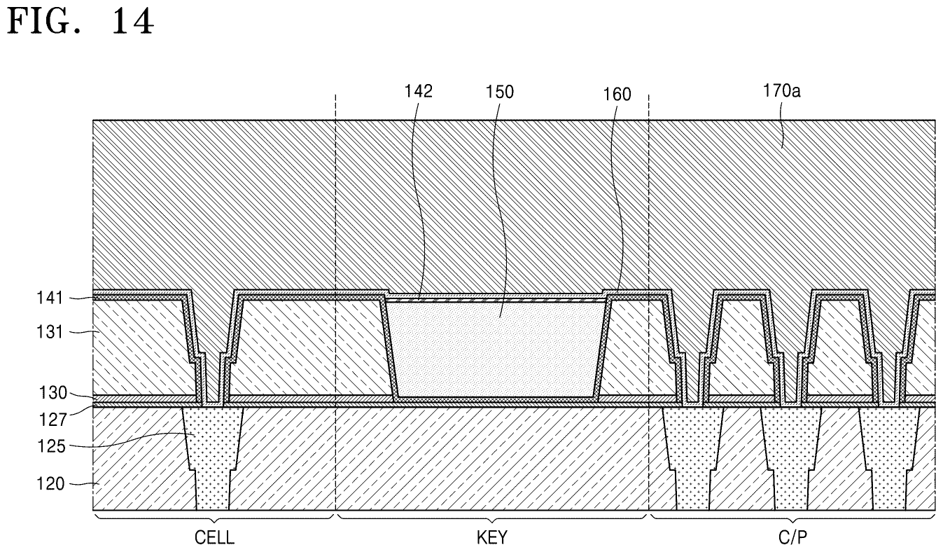

Referring to FIG. 14, an upper conductive layer 170a may be formed on the barrier metal layer 160. The upper conductive layer 170a may be formed in a bulk shape in the cell region CELL, the key region KEY, and the core/peri region C/P, entirely cover or overlap the barrier metal layer 160 formed in the cell region CELL, the key region KEY, and the core/peri region C/P, and fill or be in the recesses in the cell region CELL and the core/peri region C/P. In embodiments, the upper conductive layer 170a may include copper (Cu).

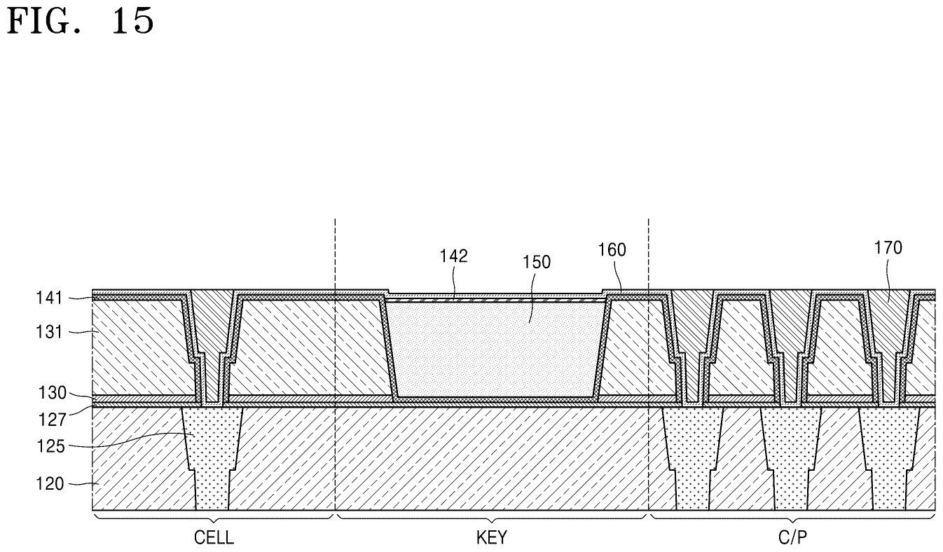

Referring to FIG. 15, an upper conductive region 170 may be formed by performing a polishing or planarization process on the upper conductive layer 170a (see FIG. 14). In embodiments, a chemical mechanical polishing (CMP) process may be formed on the upper conductive layer 170a (see FIG. 14). The upper conductive layer 170a (see FIG. 14) may be planarized until the upper surface of the barrier metal layer 160 is exposed. That is, the upper surface of the upper conductive region 170 remaining by at least partially filling the recesses in the cell region CELL and the core/peri region C/P may have the same vertical level (or height) as the upper surface of the barrier metal layer 160 relative to the lower surface of the lower interlayer insulating layer 120 in the vertical direction.

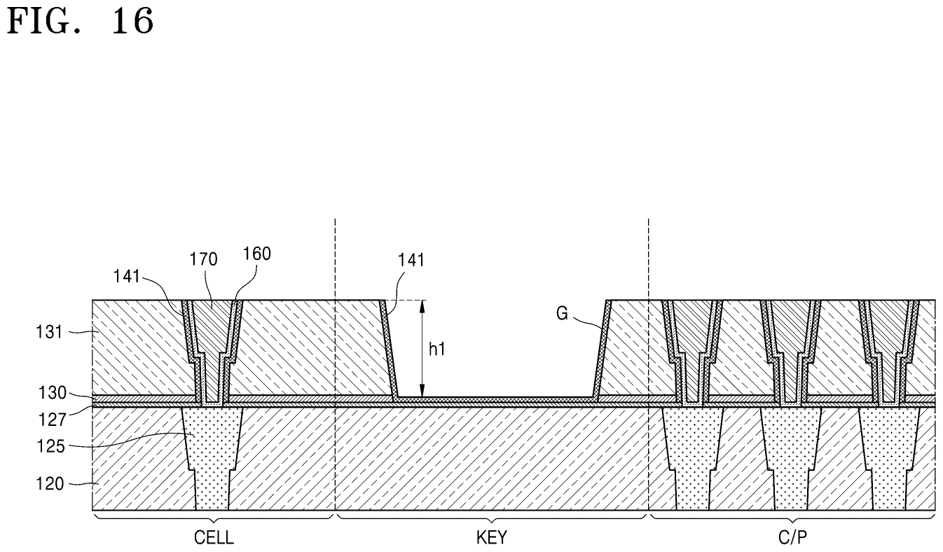

Referring to FIG. 16, the barrier metal layer 160 covering or overlapping the upper surfaces of the cell region CELL, the key region KEY, and the core/peri region C/P may be etched, the second oxide layer 142 remaining in the key region KEY may be etched, and the insulating structure 150 filling or in the first recess R1 (see FIG. 6) in the key region KEY may be removed. As a result, the upper surface of the first interlayer insulating layer 131 may be exposed in the cell region CELL and the core/peri region C/P. In the key region KEY, a gap G deposited only with the first oxide layer 141 may remain on the sidewalls and a bottom portion of the first recess R1 (see FIG. 6). In this case, the level (or height) difference of the gap G, that is, the height difference between the first oxide layer 141 deposited on a bottom portion of the gap G and the upper surface of the first interlayer insulating layer 131 relative to the lower surface of the lower interlayer insulating layer 120 in the vertical direction, may be a first height h1. In embodiments, the barrier metal layer 160 may be removed by an etchback process.

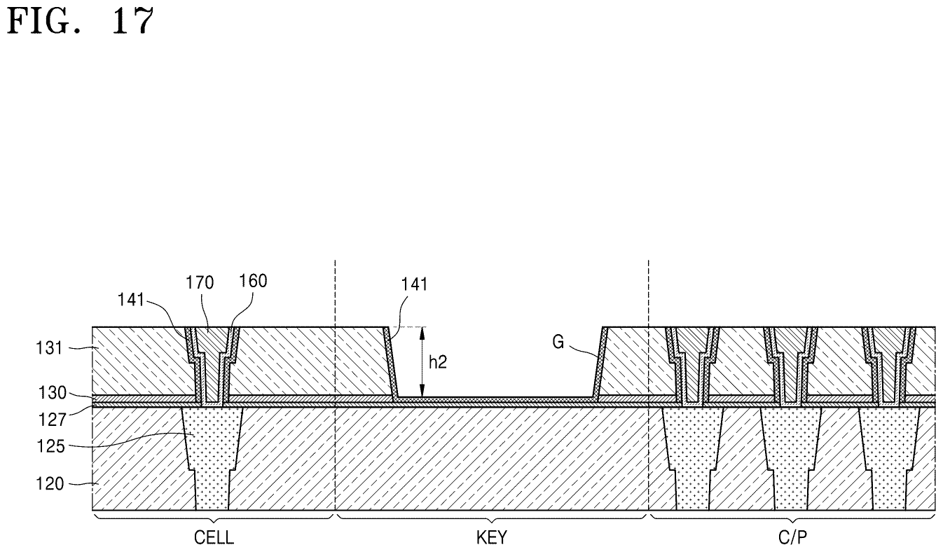

Referring to FIG. 17, a CMP process may be performed to remove portions of the upper conductive region 170 damaged by an ashing process. In this case, the level (or height) difference of the gap G of a remaining result, that is, the height difference between the first oxide layer 141 deposited on the bottom portion of the gap G and the upper surface of the first interlayer insulating layer 131 relative to the lower surface of the lower interlayer insulating layer 120 in the vertical direction, may be a second height h2. In embodiments, the second height h2 may be less than the first height h1. The second height h2 of the gap G of a result of FIG. 17 may be the level difference of the gap G in the key region KEY remaining up to a final device. In embodiments, the second height h2 may be 5000 Å or greater, but the present disclosure is not limited thereto.

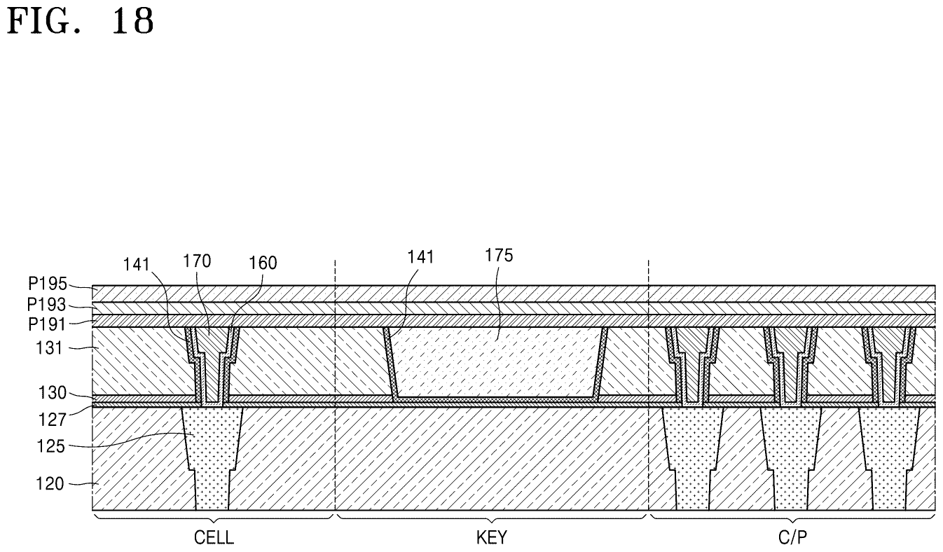

In the present disclosure, the gap G formed in the key region KEY may be used as a level (or height) difference key when a metal process for forming an MTJ structure to be described below with reference to FIGS. 18 to 21 is performed.

Referring to FIG. 18, an insulating pattern 175 filling or in the gap G (see FIG. 17) in the key region KEY may be formed, and a pre-first electrode layer P191, a pre-MTJ layer P193, and a pre-second electrode layer P195 may be sequentially formed in the cell region CELL, the key region KEY, and the core/peri region C/P.

In embodiments, the insulating pattern 175 may include an oxide layer, a SiN layer, or a combination thereof. The insulating pattern 175 may include the same material as the first interlayer insulating layer 131. Alternatively, the insulating pattern 175 may include a different material from that of the first interlayer insulating layer 131. The insulating pattern 175 may entirely fill or be in the gap G (see FIG. 17) in the key region KEY, and the upper surface of the insulating pattern 175 may have the same vertical level (or height) as the upper surface of the first interlayer insulating layer 131 relative to the lower surface of the lower interlayer insulating layer 120 in the vertical direction.

In embodiments, the pre-first electrode layer P191 and the pre-second electrode layer P195 may include at least one of metals, such as titanium and tantalum, or metal nitrides, such as titanium nitride and tantalum nitride. In some embodiments, the pre-first electrode layer P191 and the pre-second electrode layer P195 may include tungsten, Cu, platinum, Ni, silver, gold, or the like.

In embodiments, the pre-MTJ layer P193 may include a first magnetic layer (not shown), a tunnel barrier layer (not shown), and a second magnetic layer (not shown) sequentially stacked. The first magnetic layer, the tunnel barrier layer, and the second magnetic layer may correspond to the pinned layer PL, the tunnel barrier layer TBL, and the free layer FL described with reference to FIGS. 2, 3, 4A, and 4B, respectively.

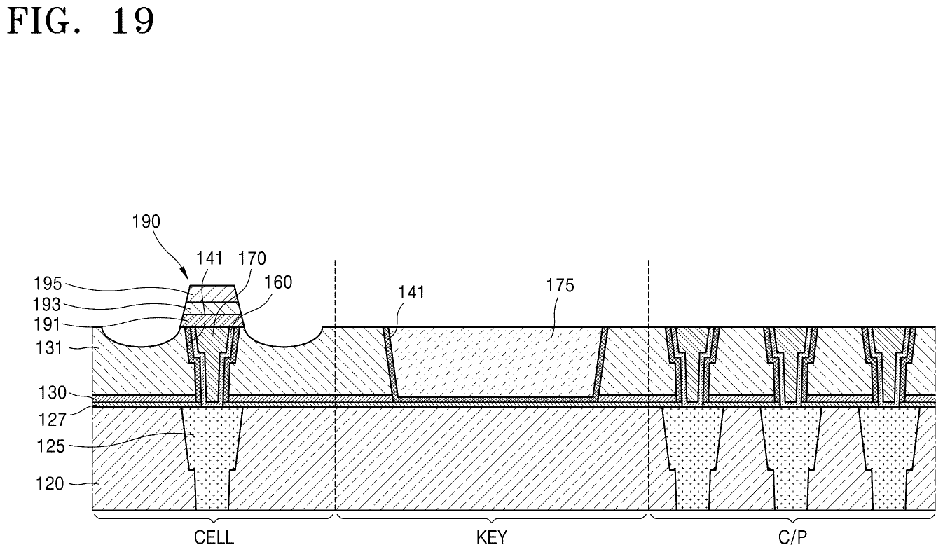

Referring to FIG. 19, a mask pattern (not shown) may be formed on the cell region CELL, the key region KEY, and the core/peri region C/P, and then the mask pattern may be used as an etching mask to pattern the pre-first electrode layer P191, the pre-MTJ layer P193, and the pre-second electrode layer P195, thereby forming an MTJ structure 190.

Particularly, all of the pre-first electrode layer P191, the pre-MTJ layer P193, and the pre-second electrode layer P195 on the key region KEY and the core/peri region C/P may be removed and the MTJ structure 190 may be formed only on the cell region CELL. By this process, the upper surface of the insulating pattern 175 described with reference to FIG. 18 may be exposed again. In addition, in a process of forming the MTJ structure 190, as shown in FIG. 19, a portion of the first interlayer insulating layer 131 in the cell region CELL may be removed.

Although FIG. 19 shows that one MTJ structure 190 is in the cell region CELL, this is only illustrative, and a plurality of MTJ structures 190 separated from each other in the horizontal direction may be formed in the cell region CELL, each MTJ structure 190 having an isolated island or elliptical/circular shape. The MTJ structure 190 may have a tapered shape having a horizontal width (e.g., a width in a horizontal direction that is parallel to the lower surface of the lower interlayer insulating layer 120) gradually decreasing away in the vertical direction that is perpendicular the lower surface of the lower interlayer insulating layer 120.

A first electrode layer 191, an MTJ layer 193, and a second electrode layer 195 of the MTJ structure 190 may be patterned portions of the pre-first electrode layer P191, the pre-MTJ layer P193, and the pre-second electrode layer P195, respectively.

The MTJ layer 193 may correspond to any one of the MTJ layers MTJ11 to MTJmn described with reference to FIG. 1.

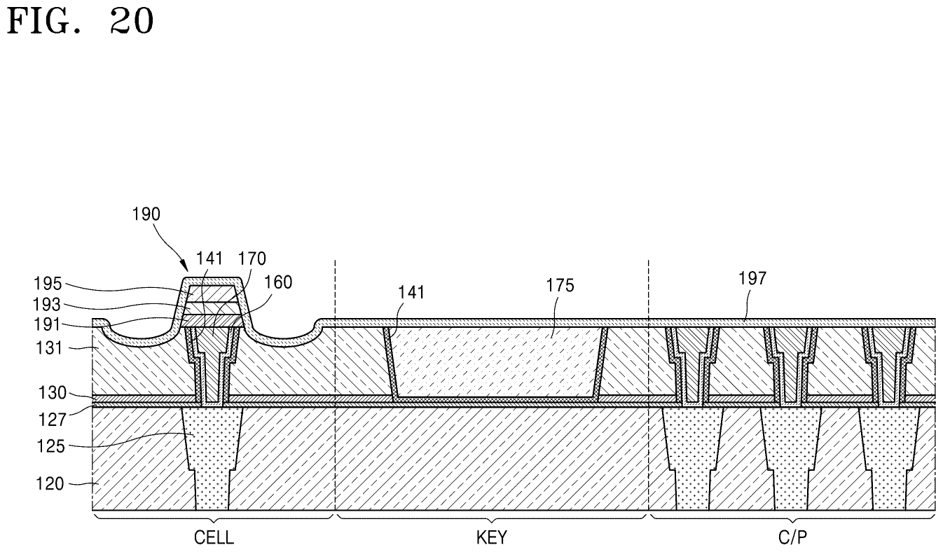

Referring to FIG. 20, a capping layer pattern 197 covering or overlapping all of the upper surface of the first interlayer insulating layer 131, the upper surface of the insulating pattern 175, and the upper surface and the side surfaces of the MTJ structure 190 may be formed. The capping layer pattern 197 may be formed with a conformal thickness on the cell region CELL, the key region KEY, and the core/peri region C/P in the vertical direction that is perpendicular the lower surface of the lower interlayer insulating layer 120.

The capping layer pattern 197 may be provided to protect the MTJ structure 190. In embodiments, the capping layer pattern 197 may include an insulating material. The capping layer pattern 197 may include, for example, SiN. The lowest portion of the capping layer pattern 197 in the cell region CELL may have a vertical level (or height) lower than the top surface of the insulating pattern 175 in the key region KEY relative to the lower surface of the lower interlayer insulating layer 120 in the vertical direction.

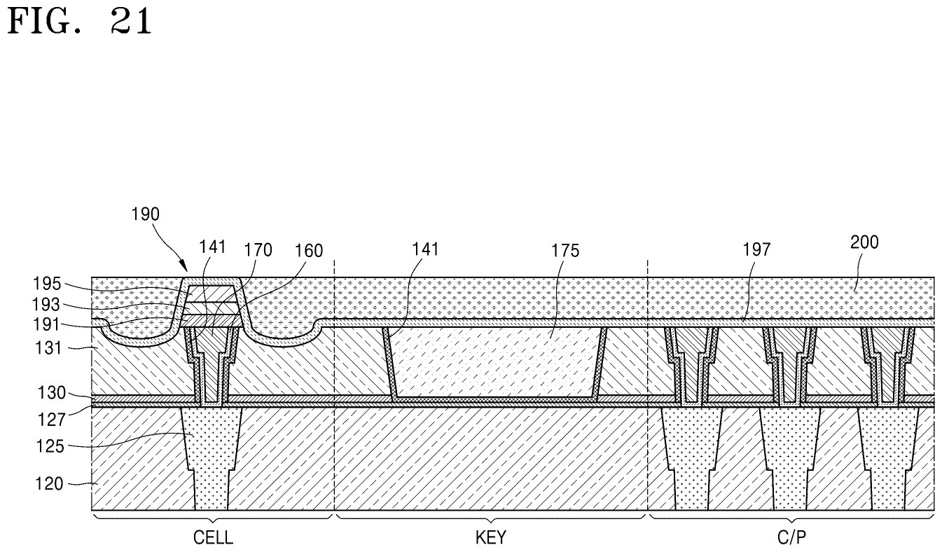

Referring to FIG. 21, an inter-wiring insulating layer 200 covering or overlapping the capping layer pattern 197 and the MTJ structure 190 may be formed. The inter-wiring insulating layer 200 may be formed to have the same vertical level (or height) at the upper surface thereof in each of the cell region CELL, the key region KEY, and the core/peri region C/P relative to the lower surface of the lower interlayer insulating layer 120 in the vertical direction.

The inter-wiring insulating layer 200 may include silicon oxide. For example, the inter-wiring insulating layer 200 may include silicon oxide formed by a high density plasma (HDP) process or be at least partially filled with an insulating material having a dielectric constant lower than that of the silicon oxide. In some embodiments, the inter-wiring insulating layer 200 may include an ultra low K (ULK) layer or an extreme low K (ELK) layer.

Although FIG. 21 shows that the MTJ structure 190 is formed on the upper conductive region 170, in another embodiment, an additional conductive region may be further formed on the upper conductive region 170 and the MTJ structure 190 may be formed on the additional conductive region.

Although the present disclosure illustrates that the process described with reference to FIGS. 6 to 21 is a portion of a process of forming a variable resistance memory, this is only illustrative, and the present disclosure is not limited thereto and may also be applied to other semiconductor devices including a Cu wiring process.

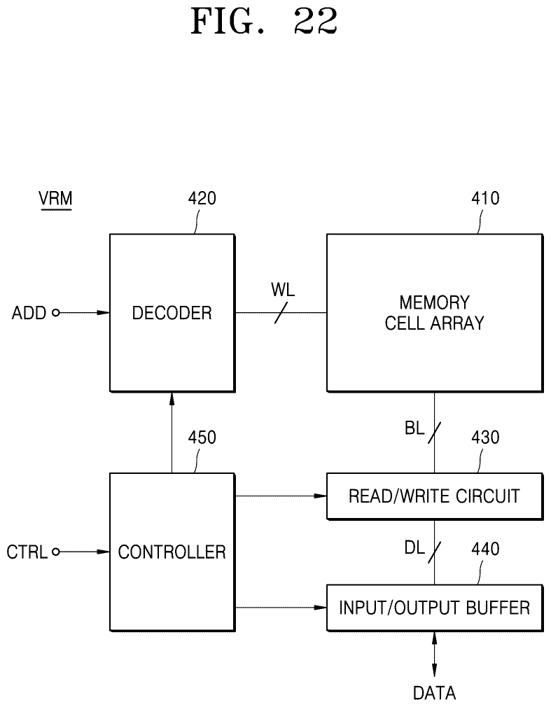

FIG. 22 is a block diagram illustrating a variable resistance memory device VRM according to some embodiments.

Particularly, the variable resistance memory device VRM according to some embodiments may include a memory cell array 410, a decoder 420, a read/write circuit 430, an input/output buffer 440, and a controller 450. The memory cell array 410 is described above, and thus, a description thereof is omitted herein.

A plurality of memory cells in the memory cell array 410 are connected to the decoder 420 through word lines WL and connected to the read/write circuit 430 through bit lines BL. The decoder 420 receives an external address ADD and decodes a row address and a column address to be accessed in the memory cell array 410, under control by the controller 450 configured to operate in response to a control signal CTRL.

The read/write circuit 430 may receive data DATA from the input/output buffer 440 through data lines DL and record the data DATA on a selected memory cell of the memory cell array 410 under control by the controller 450 or provide, to the input/output buffer 440, data read from a selected memory cell of the memory cell array 410 under control by the controller 450.

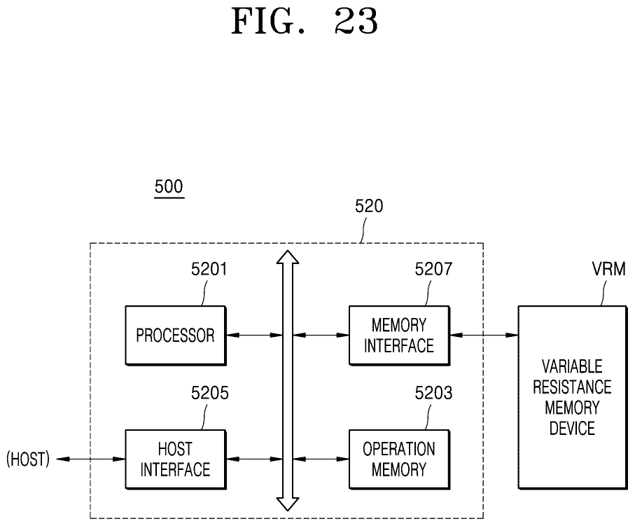

FIG. 23 is a block diagram illustrating a data processing system 500 including a variable resistance memory device VRM according to some embodiments.

Particularly, the data processing system 500 may include a memory controller 520 connected between a host and the variable resistance memory device VRM. The memory controller 520 may access the variable resistance memory device VRM in response to a request from the host.

The memory controller 520 may include a processor 5201, an operation memory 5203, a host interface 5205, and a memory interface 5207.

The processor 5201 may control a general operation of the memory controller 520, and the operation memory 5203 may store an application, data, a control signal, and the like needed to operate the memory controller 520. The host interface 5205 may perform protocol conversion for data/control signal exchange between the host and the memory controller 520.

The memory interface 5207 may perform protocol conversion for data/control signal exchange between the memory controller 520 and the variable resistance memory device VRM. The variable resistance memory device VRM is the same as described above, and thus a description thereof is omitted herein. The data processing system 500 according to some embodiments may be a memory card but is not limited thereto.

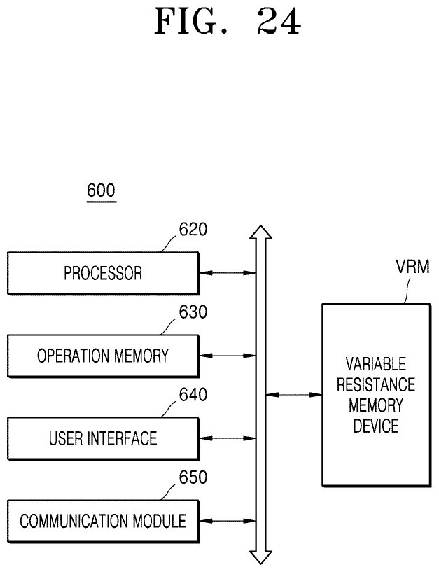

FIG. 24 is a block diagram illustrating a data processing system 600 including a variable resistance memory device VRM according to some embodiments.

Particularly, the data processing system 600 may include the variable resistance memory device VRM, a processor 620, an operation memory 630, and a user interface 640 and further include a communication module 650 in accordance with circumstances. The processor 620 may be a central processing unit.

The operation memory 630 may store an application program, data, a control signal, and the like needed to operate the data processing system 600. The user interface 640 may provide an environment in which a user is accessible to the data processing system 600 and provide a data processing process, a result, and the like of the data processing system 600 to the user.

The variable resistance memory device VRM is the same as described above, and thus a description thereof is omitted herein. The data processing system 600 may be used for a disc device, an embedded/external memory card of a portable electronic device, an image processor, and other application chipsets.

While the present disclosure has been particularly shown and described with reference to embodiments thereof, it will be understood that various changes in form and details may be made therein without departing from the scope of the following claims.

What is claimed is:

1. A semiconductor device comprising:
a semiconductor substrate that comprises a cell region, a core/peri region at least partially surrounding the cell region, and a key region between the cell region and the core/peri region;
a lower interlayer insulating layer on the cell region, the key region, and the core/peri region;
a first interlayer insulating layer on the lower interlayer insulating layer;
a first etch stop layer between the lower interlayer insulating layer and the first interlayer insulating layer; and
a lower conductive region that is on the cell region and the core/peri region and is in the lower interlayer insulating layer,
a recess that is in the first interlayer insulating layer and is on the key region; and
a first oxide layer that is on a bottom portion of the recess and is on sidewalls of the recess, and
wherein a width of an upper portion of the recess in a first direction that is parallel to a lower surface of the first interlayer insulating layer is greater than a width of the bottom portion of the recess in the first direction.

2. The semiconductor device of claim 1, wherein a lower surface of the first oxide layer is on the bottom portion of the recess and is in contact with an upper surface of the first etch stop layer.

3. The semiconductor device of claim 1, further comprising an upper conductive region that is in the first interlayer insulating layer and is on the cell region and the core/peri region, wherein the upper conductive region is on an upper surface of the lower conductive region.

4. The semiconductor device of claim 3, wherein the upper conductive region and the lower conductive region comprise copper (Cu).

5. The semiconductor device of claim 3, further comprising:
a barrier metal layer that at least partially surrounds a bottom portion of the upper conductive region and sidewalls of the upper conductive region; and
an outer oxide layer that at least partially surrounds an outer wall of the barrier metal layer.

6. The semiconductor device of claim 5, wherein the outer oxide layer comprises a substantially same material as the first oxide layer.

7. The semiconductor device of claim 5, wherein the barrier metal layer comprises at least one selected from aluminum (Al), titanium (Ti), tantalum (Ta), and metal oxide.

8. The semiconductor device of claim 3, further comprising, an electrode that is on the cell region and is on the upper conductive region and a magnetic tunnel junction (MTJ) structure on the electrode.

9. The semiconductor device of claim 1, further comprising a liner that has a uniform thickness in a second direction that is perpendicular to the first direction, is on the key region and the first etch stop layer, and is free from overlap with the bottom portion of the recess in the second direction.

10. The semiconductor device of claim 9, wherein the liner comprises aluminum nitride.

11. The semiconductor device of claim 1, wherein a depth of the recess in a second direction that is perpendicular to the first direction is greater than or equal to 5000 Å.

12. A semiconductor device comprising:
a semiconductor substrate that comprises a cell region, a key region adjacent to the cell region, and a core/peri region at least partially surrounding the cell region and the key region;
a lower interlayer insulating layer on the cell region, the key region, and the core/peri region;
a lower conductive region that is on the cell region and the core/peri region and is in the lower interlayer insulating layer;
a first etch stop layer on the lower interlayer insulating layer;
a liner on the first etch stop layer;
a first interlayer insulating layer on the liner;
an upper conductive region that is in the first interlayer insulating layer and at least partially overlaps the lower conductive region in a first direction that is perpendicular to a lower surface of the lower interlayer insulating layer;
at least one recess, wherein a width of an upper portion of each of the at least one recess in a second direction that is perpendicular to the first direction is greater than a width of a bottom portion of each of the at least one recess in the second direction; and
a first oxide layer that has a uniform thickness in the first direction and is on the bottom portion of each of the at least one recess and sidewalls of each of the at least one recess.

13. The semiconductor device of claim 12, wherein the bottom portion of each of the at least one recess is in contact with the first etch stop layer.

14. The semiconductor device of claim 12, further comprising:
a barrier metal layer that at least partially surrounds a bottom portion of the upper conductive region and sidewalls of the upper conductive region; and
an outer oxide layer that at least partially surrounds an outer wall of the barrier metal layer.

15. The semiconductor device of claim 14, wherein the outer oxide layer comprises a substantially same material as the first oxide layer, and wherein a thickness of the outer oxide layer in the second direction is a substantially same thickness as the first oxide layer in the second direction.

16. The semiconductor device of claim 12, wherein a depth of each of the at least one recess in the first direction is greater than or equal to 5000 Å.

17. The semiconductor device of claim 12, wherein the upper conductive region and the lower conductive region comprise copper, and wherein the liner comprises aluminum nitride.

18. The semiconductor device of claim 12, wherein the key region does not comprise copper.

19. A semiconductor device comprising:
a substrate that comprises a cell region, a key region and a core/peri region;
a lower interlayer insulating layer on the cell region, the key region, and the core/peri region;
a lower conductive region that is on the cell region and the core/peri region and is in the lower interlayer insulating layer;
a first etch stop layer on the lower interlayer insulating layer;
a liner on the first etch stop layer;
a first interlayer insulating layer on the liner;
an upper conductive region that at least partially overlaps the lower conductive region in a first direction that is perpendicular to a lower surface of the lower interlayer insulating layer;
a barrier metal layer that at least partially surrounds a bottom portion of the upper conductive region and sidewalls of the upper conductive region;
an outer oxide layer that at least partially surrounds an outer wall of the barrier metal layer and is in the first interlayer insulating layer;
at least one recess that is in the first interlayer insulating layer and is on the key region, wherein each of the at least one recess comprises sidewalls that are sloped in the first direction; and
a first oxide layer that has a uniform thickness in the first direction, contacts the first etch stop layer, is on the sidewalls of each of the at least one recess,
wherein the outer oxide layer comprises a substantially same material as the first oxide layer, and
wherein a thickness of the outer oxide layer in a second direction that is perpendicular to the first direction is substantially the same as a thickness of the first oxide layer in the second direction.

20. The semiconductor device of claim 19, wherein a depth of each of the at least one recess in the first direction is greater than or equal to 5000 Å.
